(19) United States
(12) Patent Application Publication
(10) Pub. No.: US 2007/0111479 A1
(43) Pub. Date: May 17, 2007

(54) High-power-laser chip-fabrication apparatus and method thereof

(76) Inventor: Chih-Ming Hsu, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/648,585

(22) Filed: Jan. 3, 2007

Related U.S. Application Data
(62) Division of application No. 11/203,193, filed on Aug. 15, 2005.

(30) Foreign Application Priority Data
Dec. 14, 2004 (TW) 093138746

(51) Int. Cl. B44C 1/22; H01L 21/00

(52) U.S. Cl. 438/462; 216/65; 257/E21.238

(57) ABSTRACT

The present invention discloses a high-power-laser chip-fabrication apparatus and a method thereof, wherein a substrate is fixed on a working table; a light-guide device is used to direct a high power laser to a scribed line on the substrate; a control device is used to position the working table and the high power laser so that the high power laser can be precisely aimed at the scribed line to be cut; a video device is used to observe whether the high power has been aimed at the scribed line; an object lens is used to adjust the focal length by which the high power laser is to be aimed at one of the scribed lines; the length of the scribed line to be cut and the spacing between two scribed lines are input; and then, the cutting is performed. The present invention can cut the substrate quickly and precisely into multiple discrete chips and accelerate the fabrication process.

### RELATED APPLICATIONS

This application is a Divisional patent application of co-pending application Ser. No. 11/203,193, filed on 15 Aug. 2005.

### BACKGROUND OF THE INVENTION

1. Field of the Invention

The present invention relates to a chip-fabrication apparatus and a method thereof, particularly to a high-power-laser chip-fabrication apparatus and a method thereof.

2. Description of the Related Art

Laser, i.e. Light Amplification by Simulated Emission of Radiation, is a very important invention in modem science and has the characteristics of high power density, high monochromaticity, high directivity, and high coherency. Laser is extensively used in medicine, communication, information, industry, etc., and has contributed so much thereto.

In comparison with silicon chips the current mainstream of the electronic industry, metallic chips, such as diamond chips, are expected to have twice the transmission rate of silicon chips; thus, electronic elements, such as transistors, which are made of diamond chips, are expected to have higher speed than those made of silicon chips. Besides, diamond chips have higher hardness and higher heat resistance. Therefore, there is a tendency to replace silicon chips with diamond chips.

However, a diamond substrate is hard to cut because of its high hardness, and dicing a diamond substrate with a diamond blade is also very time-consuming.

Accordingly, the present proposes a high-power-laser chip-fabrication apparatus and a method thereof to overcome the abovementioned problems.

### SUMMARY OF THE INVENTION

The primary objective of the present invention is to provide a high-power-laser chip-fabrication apparatus and a method thereof, wherein a high power laser having a power higher than 0.8 w is used to break metallic bonds of a metallic substrate to ablate some portion of the substrate in order to cut scribed lines and separate the substrate into multiple discrete chips.

Another objective of the present invention is to provide a high-power-laser chip-fabrication apparatus and a method thereof, wherein a substrate is rapidly and perfectly cut with a high power laser so that the yield can be raised.

To achieve the abovementioned objective, the present proposes a high-power-laser chip-fabrication apparatus, which comprises: a working table, having a vacuum device to fix a substrate having multiple chips with a scribed line drawn between every two chips; a high power laser, having a power higher than 0.8 w to cut the substrate into multiple discrete chips; a light-guide device, coupled to the high power laser, and directing the high power laser to the substrate; and a control device, coupled to the working table, the high power laser and the light-guide device, and controlling the positions of the working table and the high power laser so that the high power can be aimed at the scribed lines on the substrate for cutting the substrate.

The present invention also proposes a high-power-laser chip-fabrication method, wherein firstly, a substrate having multiple chips is provided, with a scribed line drawn between every two chips; next, the substrate is disposed on a working table and fixed with a vacuum device; next, a control device is used to position the working table and a high power laser so that the high power can be aimed at the scribed line to be cut; next, the length of the scribed line to be cut and the spacing between the scribed line to be cut and the scribed line to be cut next are input; and lastly, the scribed lines are sequentially cut in order to separate the substrate into multiple discrete chips.

To enable the objectives, technical contents, characteristics, and accomplishments of the present invention to be more easily understood, the embodiments of the present invention are to be described below in detail in cooperation with the attached drawings.

### BRIEF DESCRIPTION OF THE DRAWINGS

FIG. 1 is a schematic block diagram showing the high-power-laser chip-fabrication apparatus according to the present invention.

FIG. 2 is a flowchart of the high-power-laser chip-fabrication method according to the present invention.

### DETAILED DESCRIPTION OF THE INVENTION

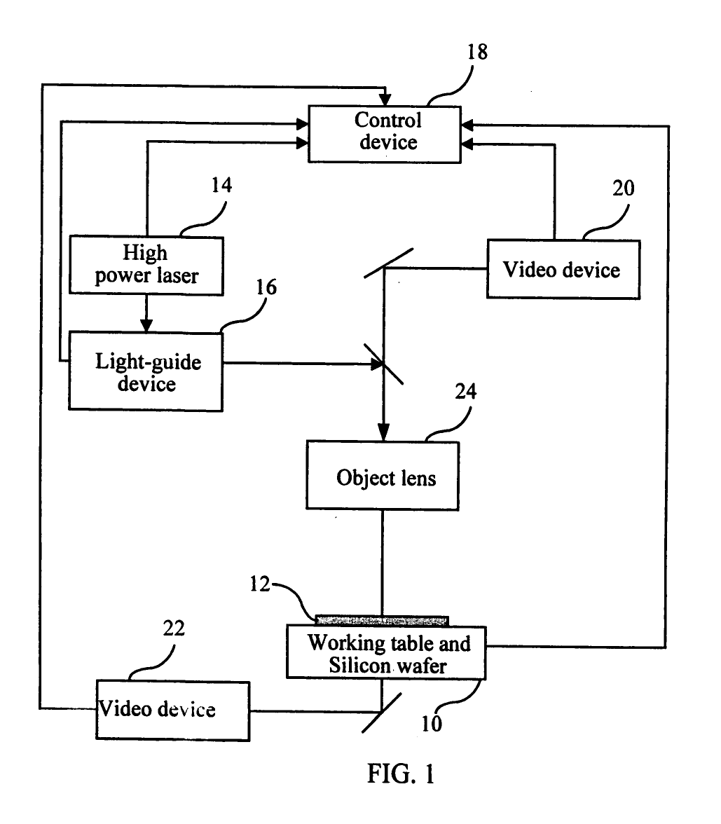

The present proposes a high-power-laser chip-fabrication apparatus. Refer to FIG. 1 a schematic block diagram showing the high-power-laser chip-fabrication apparatus according to the present invention. The high-power-laser chip-fabrication apparatus comprises: a working table 10, having a vacuum device to fix a substrate 12, such as a metallic substrate or a diamond substrate, wherein before being fixed to the working table 10, the substrate 12 can be stuck onto a holding film beforehand for its planarity, and the substrate 12 has multiple chips with a scribed line drawn between every two chips; a high power laser 14, used to cut the scribed lines on the substrate 12; a light-guide device 16, coupled to the high power laser 14 and the working table 10, and directing the high power laser 14 to the substrate 12; and a control device 18 (such as a computer), used to control the working table 10, the high power laser 14 and the light-guide device 16 in order to position the working table 10, the high power laser 14 so that the high power laser 14 can be sequentially aimed at the scribed lines on the substrate 12 for cutting the substrate 12.

The high-power-laser chip-fabrication apparatus can further comprises: two video devices 20, 22, coupled to the working table 10 and the control device 18, and separately disposed above and below the working table 10, and controlled by the control device 18 to observe whether the high power laser 14 has been precisely aimed at one of the scribed lines on the substrate 12; and an object lens 24, disposed between the working table 10 and the light-guide device 16, and used to adjust the focal length by which the high power laser 14 is to be aimed at one of said scribed lines.

In the present invention, the thickness of the substrate 12 ranges from 10 to 100 μm; the power of the high power laser should be higher than 0.8 w; the parameters of the high power laser include: wavelength ranging from 138 to 370 nm, frequency ranging from 40 to 80 KHz, energy density ranging from 40 to 100 J/cm², pulse duration ranging from 1 to 35 nanosecond, and light spot size ranging from 10 to 30 μm.

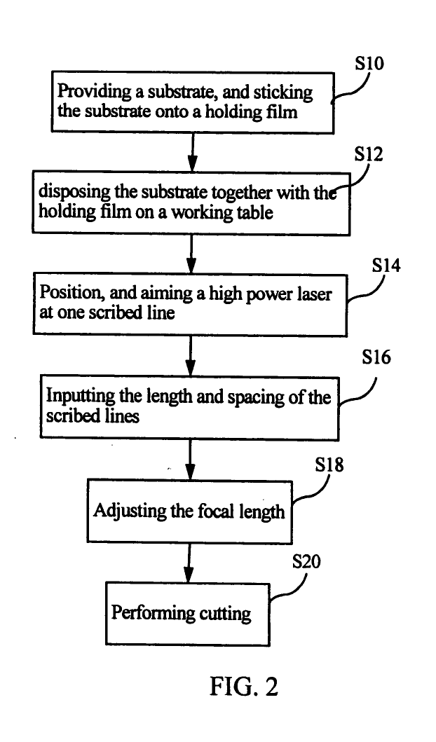

Refer to FIG. 2. The present invention further proposes a high-power-laser chip-fabrication method, which comprises the following steps: firstly, providing a substrate, which has multiple chips with a scribed line drawn between every two chips, and sticking the substrate onto a holding film (S10); next, disposing the substrate together with the holding film on a working table having a vacuum device, and fixing them with the vacuum device (S12); next, utilizing a light-guide device to direct a high power laser to the substrate, and utilizing a control device to position the working table and the high power laser, i.e. to adjust their X and Y coordinates, to enable the high power laser to be aimed at one scribed line to be cut, and utilizing a video device to observe whether the high power laser has been precisely aimed at the scribed line to be cut (S14); next, inputting into the control device the length of the scribed line to be cut, the spacing between the scribed line to be cut and the scribed line to be cut next, the moving speed of the working table, and the parameters of the high power laser, such as wavelength, frequency, energy and duration (S16); next, utilizing an object lens to adjust the focal length from the high power laser to the substrate, i.e. to adjust its Z coordinate, and utilizing the video device to observe whether the high power laser has been precisely aimed at the scribed line (S18); and lastly, utilizing the high power laser to sequentially cut the scribed lines into a depth larger than the thickness of the substrate in order to separate the substrate into multiple discrete chips (S20).

After completing the step S20, the high power laser will stop automatically, and then, the vacuum device of the working table will be shut, and the cut substrate will be taken out.

In summary, the present invention proposes a high-power-laser chip-fabrication apparatus and a method thereof, wherein a high power laser having a power higher than 0.8w is used to break metallic bonds of a metallic substrate to ablate some portion of the substrate in order to precisely and perfectly cut the scribed lines and separate the substrate into multiple discrete chips, so that the yield can be raised.

Those embodiments described above are only to clarify the present invention to enable the persons skilled in the art to understand, make, and use the present invention but not intended to limit the scope of the present invention. Any equivalent modification or variation without departing from the spirit of the present invention disclosed herein is to be included within the scope of the claims stated below.

What is claimed is:

1. A high-power-laser chip-fabrication method, comprising the following steps:
providing a substrate having multiple chips with a scribed line drawn between every two said chips;
disposing said substrate on a working table having a vacuum device to fix said substrate;
utilizing at least one control device to position said working table and a high power laser to enable said high power laser to be aimed at one said scribed line to be cut;
inputting the length of one said scribed line to be cut and the spacing between said scribed line to be cut and another said scribed line to be cut next; and
sequentially cutting said scribed lines to separate said substrate into multiple discrete said chips.

2. The high-power-laser chip-fabrication method according to claim 1, wherein said substrate is stuck onto a holding film, and then, said substrate together with said holding film is disposed on said working table.

3. The high-power-laser chip-fabrication method according to claim 1, wherein said control device can control said working table to move and rotate said substrate.

4. The high-power-laser chip-fabrication method according to claim 1, wherein the moving speed of said working table and the parameters by which said high power laser cuts said scribed lines can be input into said control device.

5. The high-power-laser chip-fabrication method according to claim 4, wherein said parameters include: wavelength, frequency, energy and duration.

6. The high-power-laser chip-fabrication method according to claim 1, further comprising a step of “utilizing a light-guide device to direct said high power laser to said substrate” before said step of “utilizing at least one control device to position said working table and a high power laser”.

7. The high-power-laser chip-fabrication method according to claim 1, wherein during said step of “to enable said high power laser to be aimed at one said scribed line to be cut”, an object lens is simultaneously used to adjust the focal length by which said high power laser is to be aimed at said scribed line.

8. The high-power-laser chip-fabrication method according to claim 1, wherein during said step of “to enable said high power laser to be aimed at one said scribed line to be cut”, said control device utilizes at least one video device to observe whether said high power laser has been precisely aimed at said scribed line.

9. The high-power-laser chip-fabrication method according to claim 1, wherein said high power laser cuts said scribed lines into a depth larger than the thickness of said substrate for complete cutting of said scribed lines.

10. The high-power-laser chip-fabrication method according to claim 1, wherein after said step of “sequentially cutting said scribed lines to separate said substrate into multiple discrete said chips”, said high power laser automatically stops cutting.

11. The high-power-laser chip-fabrication method according to claim 10, further comprising a step of “shutting said vacuum device of said working table and taking off said substrate” after said step of “said high power laser automatically stops cutting”.
